(19) United States
(12) Patent Application Publication
(10) Pub. No.: US 2018/0004357 A1
(43) Pub. Date: Jan. 4, 2018

(54) PIEZOELECTRIC PACKAGE-INTEGRATED SURFACE ACOUSTIC WAVE SENSING DEVICES

(71) Applicant: Intel Corporation, Santa Clara, CA (US)

(72) Inventors: Adel A. ELSHERBINI, Chandler, AZ (US); Feras EID, Chandler, AZ (US); Sasha N. OSTER, Chandler, AZ (US); Georgios C. DOGIAMIS, Chandler, AZ (US); Thomas L. SOUNART, Chandler, AZ (US); Johanna M. SWAN, Scottsdale, AZ (US); Shawna M. LIFF, Scottsdale, AZ (US)

(73) Assignee: Intel Corporation, Santa Clara, CA (US)

(21) Appl. No.: 15/199,906

(22) Filed: Jun. 30, 2016

(51) Int. Cl. G06F 3/043; H03H 9/25; G06F 3/041

(52) U.S. Cl. CPC G06F 3/0436; G06F 3/0416; H03H 9/25

(57) ABSTRACT

Embodiments of the invention include an acoustic sensing device having a piezoelectric transmit transducer to receive input electrical signals and to generate a surface acoustic wave to be transmitted along a surface of the sensing device which is integrated with an organic substrate. The sensing device also includes a piezoelectric receive transducer to receive the surface acoustic wave and to generate output electrical signals and an input region integrated with the organic substrate. The input region is capable of receiving input which changes an acoustic amplitude of the surface acoustic wave.

### FIELD OF THE INVENTION

Embodiments of the present invention relate generally to package integrated sensing devices. In particular, embodiments of the present invention relate to piezoelectric package integrated surface acoustic wave sensing devices.

### BACKGROUND OF THE INVENTION

Compact, low profile and scalable input techniques are required in many wearables, internet of things (IoT), and mobile systems. However, input buttons are typically relatively tall (1 mm or more), consume a large area, and provide limited input capabilities with no gesture recognition.

Capacitive or resistive touch input arrays have a much lower Z-height and can provide gesture capabilities (e.g., up to 10 fingers simultaneous detection). However, they are relatively expensive and require conductive lines to detect capacitance or resistance change. This limits the areas where they can be used to only on top of displays or as a separate module on top of other components such as for laptop touchpads. Optical input techniques require cameras which are relatively expensive and have tall Z-height for the lenses module. Also, optical input techniques require complex processing to detect the input which results in high power consumption that is particularly detrimental for mobile systems where battery life is very important.

### BRIEF DESCRIPTION OF THE DRAWINGS

FIG. 1 illustrates a top view of a microelectronic device having a package-integrated piezoelectric SAW sensing device, according to an embodiment.

FIG. 2 illustrates a top view of a microelectronic device having a package-integrated piezoelectric SAW sensing device, according to an embodiment.

FIG. 3 illustrates a side view of a microelectronic device 300 having package-integrated piezoelectric devices, according to an embodiment.

FIG. 4A illustrates a side view of a package substrate 400 having a package-integrated piezoelectric SAW sensing device (e.g., touch sensor), according to one embodiment.

FIG. 4B illustrates a top view of a package substrate 400 having a package-integrated piezoelectric SAW sensing device (e.g., touch sensor), according to one embodiment.

FIG. 5 illustrates a computing device 1500 in accordance with one embodiment of the invention.

### DETAILED DESCRIPTION OF THE INVENTION

Described herein are piezoelectric package integrated surface acoustic wave sensing devices. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order to not obscure the illustrative implementations.

Various operations will be described as multiple discrete operations, in turn, in a manner that is most helpful in understanding the present invention. However, the order of description should not be construed to imply that these operations are necessarily order dependent. In particular, these operations need not be performed in the order of presentation.

The present design provides thin, low cost surface acoustic wave (SAW) sensing devices that are manufactured as part of an organic package substrate traditionally used to route signals between the CPU or other die and the board. The SAW sensing devices can be implemented with small form factor wearables and IoT devices. The SAW sensing devices consume very little area on a system board, can share area with other components, and have very small Z-height.

The present design results in package-integrated piezoelectric SAW sensing devices, thus enabling thinner systems, tighter integration and more compact form factor in comparison to systems with discrete assembled input devices. For the present design, the sensing devices are directly created as part of the substrate itself with no need for assembling external components.

The present design can be manufactured as part of the substrate fabrication process with no need for purchasing and assembling discrete components. It therefore enables high volume manufacturability (and thus lower costs) of systems that need acoustic wave sensing. Package substrate technology using organic panel-level (e.g., ˜0.5 m×0.5 m sized panels) high volume manufacturing (HVM) processes has significant cost advantages compared to silicon-based MEMS processes since it allows the batch fabrication of more devices using less expensive materials. However, the deposition of high quality piezoelectric thin films has been traditionally limited to inorganic substrates such as silicon and other ceramics due to their ability to withstand the high temperatures required for crystallizing those films. The present design is enabled by a new process to allow the deposition and crystallization of high quality piezoelectric thin films without degrading the organic substrate.

In one example, the present design includes package-integrated structures to act as acoustic sensing devices. Those structures are manufactured as part of the package layers. The acoustic sensing devices have a much smaller Z-height (e.g., significantly less than 1 mm, with no added Z-height on top of the package substrate) in comparison to an input button. The acoustic sensing devices have lower cost and can share area with other components in comparison to capacitive or resistive touch input arrays. The acoustic sensing devices have smaller Z-height and lower cost than optical techniques.

Compared to conventional approaches for input devices, the present design provides the unique advantage of easy integration with components on the same side of the substrate and minimal added size.

The acoustic sensing device structures include piezoelectric materials that are deposited and patterned layer-by-layer into the package. Piezoelectric material deposition (e.g., 0.5 to 1 um deposition thickness) and crystallization also occur in the package substrate during the package fabrication process. An annealing operation at a substrate temperature range (e.g., up to 260° C.) that is lower than typically used for piezoelectric material annealing allows crystallization of the piezoelectric material (e.g., lead zirconate titanate (PZT), potassium sodium niobate (KNN), aluminum nitride (AlN), zinc oxide (ZnO), etc) to occur during the package fabrication process without imparting thermal degradation or damage to the substrate layers. In one example, laser pulsed annealing occurs locally with respect to the piezoelectric material without damaging other layers of the package substrate (e.g., organic substrate) including organic layers.

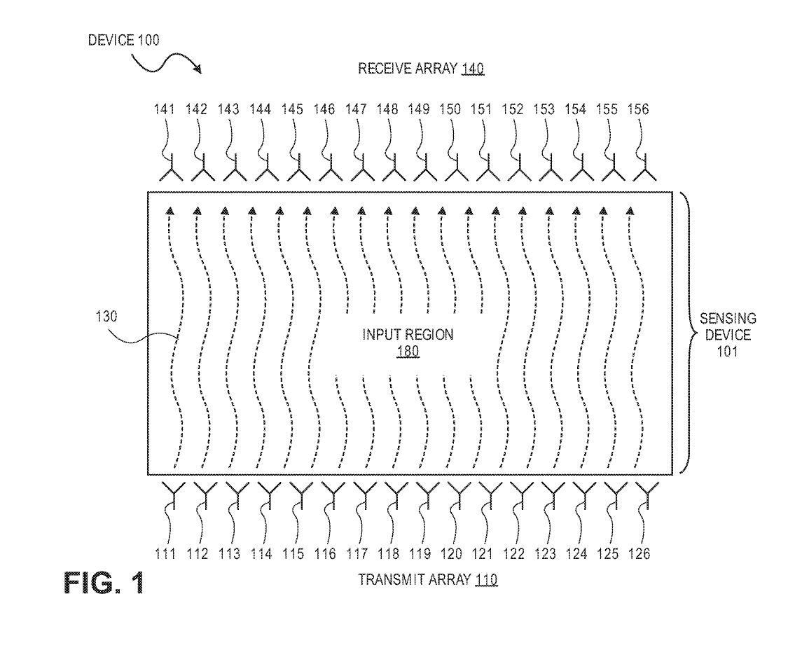

FIG. 1 illustrates a top view of a microelectronic device having a package-integrated piezoelectric SAW sensing device, according to an embodiment. In one example, the device 100 may be coupled or attached to multiple devices (e.g., die, chip, CPU, silicon die or chip, RF transceiver, etc.) and may be a package substrate, a printed circuit board (PCB), or a combination of a package substrate and a PCB. The device 100 (e.g., organic substrate) includes organic dielectric layers and conductive layers. The device 100 can be formed during package substrate processing (e.g., at panel level). In one example, a piezoelectric SAW sensing device is formed with conductive vibrating structures and piezoelectric material. The SAW sensing device 101 (or transducer device) includes a transmit array 110 having transmitters 111-126 that generate acoustic waves (e.g., 130) which are received by a receive array 140 having receivers 141-156.

The sensing device 101 can be a piezoelectric, package-integrated or board integrated transducer array as shown in FIG. 1. The transmit array 110 generates surface acoustic waves along the surface of the device 101. When an input (e.g., user's touch, stylus, any object, etc.) contacts the surface of an input region 180 (e.g., input area, touch area) or is located in close proximity to the input region (for highly sensitive receivers), the acoustic wave is attenuated and this attenuation is detected by the receive array 140. By detecting a level of receive power, a location of the input can be determined. The transmit and receive arrays can be on two sides of the device 100 as shown in FIG. 1 for simple small wearables and IoT devices (e.g., sound volume slider or temperature setting) or on the four sides of device 100 for larger devices.

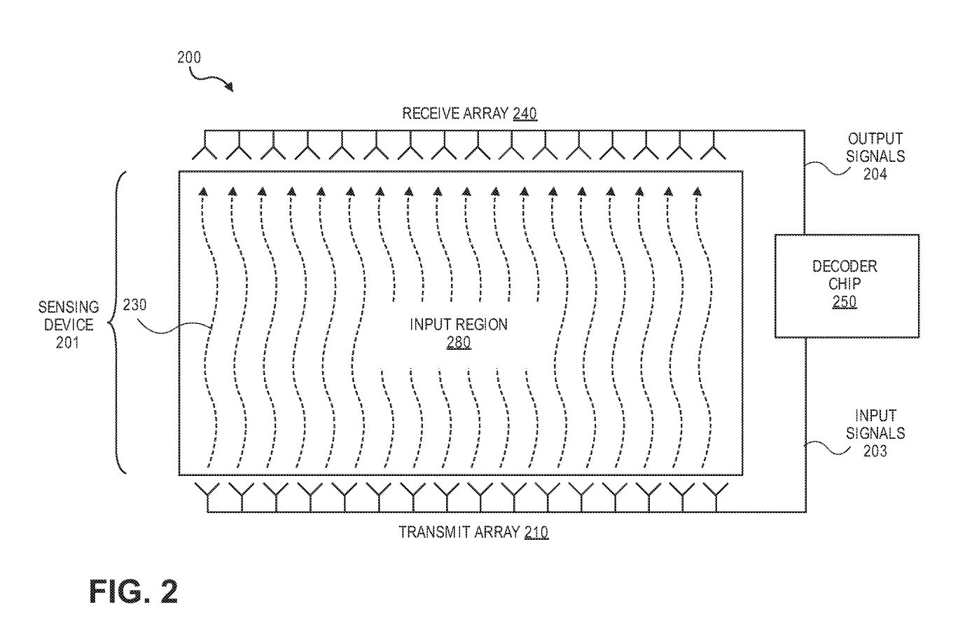

FIG. 2 illustrates a top view of a microelectronic device having a package-integrated piezoelectric SAW sensing device, according to an embodiment. In one example, the device 200 may be coupled or attached to multiple devices (e.g., die, chip, CPU, silicon die or chip, RF transceiver, etc.) and may be a package substrate, a printed circuit board (PCB), or a combination of a package substrate and a PCB. The device 200 (e.g., organic substrate) includes organic dielectric layers and conductive layers. The device 200 can be formed during package substrate processing (e.g., at panel level). In one example, a piezoelectric SAW sensing device is formed with conductive vibrating structures and piezoelectric material. The SAW sensing device 201 (or transducer device) includes a transmit array 210 having transmitters that generate acoustic waves (e.g., 230) which are received by a receive array 240.

The sensing device 201 can be a piezoelectric, package-integrated or board integrated transducer array as shown in FIG. 2. The transmit array 210 generates surface acoustic waves along the surface of the device 201. When an input (e.g., user's touch, stylus, any object, etc.) contacts the surface of the input region 280 (e.g., input area, touch area) or is located in close proximity to the input region (for highly sensitive receivers), the acoustic wave is attenuated and this attenuation is detected by the receive array 240. The transmit array and receive arrays include piezoelectric transducer elements that are integrated with a package substrate or a PCB. The transmit transducers convert input signals 203 having electrical energy into surface acoustic waves on the sensing device 201. The receive transducers receive the surface acoustic waves and convert these into output signals 204 having electrical energy. The decoder 250 (e.g., decoder chip) periodically provides the input signals 203 used to excite the transmitters of the transmit array 210, and also receives the electrical energy of the output signals 204 generated by the receive array 240 in a scanning configuration. When an input (e.g., a user's touch, stylus, any object, etc.) contacts any location on the input region 280, which may be integrated with a touch screen, the receive array 240 associated with the touch area 280 detects a lower acoustic amplitude and generates a corresponding electrical signal that is picked up by the decoder 250 and sent to a main processor that is located on the device 200. The decoder 250 can also be part of the CPU.

By detecting a level of receive power based on a received acoustic amplitude and the time the acoustic signal was transmitted, a location of the input and potentially pressing force level can be determined. The arrays can be on two sides of the device as shown in FIG. 2 for simple small wearables and IoT devices (e.g., sound volume slider or temperature setting) or on 4 sides of the device for larger devices.

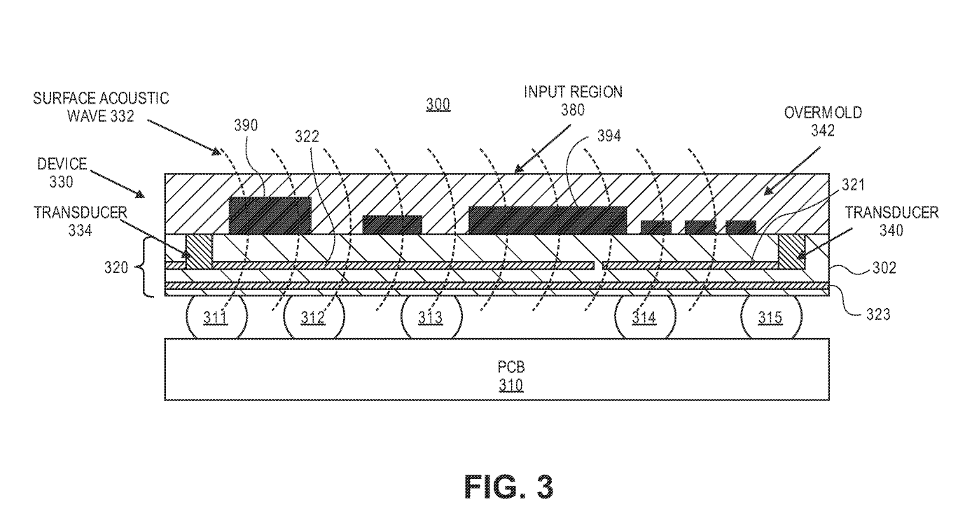

Referring now to FIG. 3, a side view of a microelectronic device 300 having package-integrated piezoelectric devices is shown, according to an embodiment. In one example, the microelectronic device 300 includes multiple devices 390 and 394 (e.g., die, chip, CPU, silicon die or chip, radio transceiver, etc.) that are coupled or attached to a package substrate 320. In one example, the package substrate 320 is coupled or attached to the printed circuit board (PCB) 310 using, for example, solder balls 311 through 315.

The package substrate 320 (e.g., organic substrate) includes organic dielectric layers 302 and conductive layers 321-323. Organic materials may include any type of organic material such as flame retardant 4 (FR4), resin-filled polymers, prepreg (e.g., pre impregnated, fiber weave impregnated with a resin bonding agent), polymers, silica-filled polymers, etc. The package substrate 320 can be formed during package substrate processing (e.g., at panel level). The panels formed can be large (e.g., having in-plane (x, y) dimensions of approximately 0.5 meter by 0.5 meter, or greater than 0.5 meter, etc.) for lower cost. In one example, a piezoelectric SAW sensing device 330 (e.g., acoustic transducer device) is formed with input transmit transducer 334, output receive transducer 340, and touch surface 380. The transducer 334 generates surface acoustic wave 332 which is received by the output receive transducer 340.

The decoder (e.g., decoder chip 390) periodically provides input signals used to excite the input transmit transducer 334, and also receives the electrical energy of output signals generated by the receive transducer 340. When an input (e.g., a user's touch, stylus, any object, etc.) contacts any location on an input region 380 (e.g., input area, touch surface) or is located in close proximity to the input region, which may be integrated with a touch screen, the transducer 340 associated with the input region 380 detects a lower acoustic amplitude and generates a corresponding electrical signal that is picked up by the decoder and sent to a main processor (e.g., 394) that is located on the device 300.

The input region 380 may be formed above components (e.g., 390, 394) that can be potentially overmolded with overmold 342. In one example, this is extremely useful as a low volume adder input structure for many IoT devices and wearable devices. The overmold 342 is optional for touch sensing but also provides protection to nearby devices from the user input or other input.

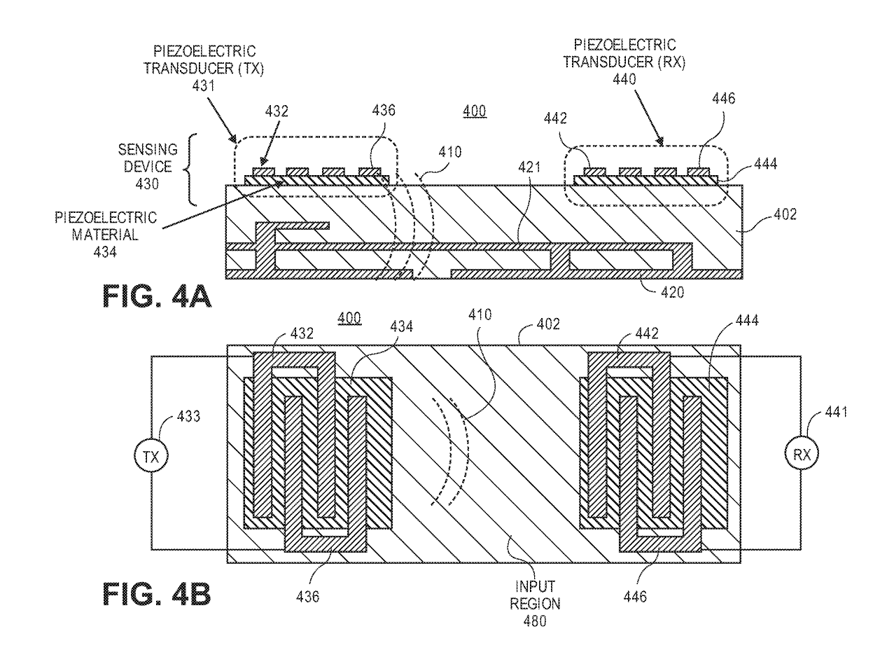

FIG. 4A illustrates a side view of a package substrate 400 having a package-integrated piezoelectric SAW sensing device (e.g., touch sensor), according to one embodiment. The package substrate 400 (e.g., organic substrate), which includes organic dielectric layers 402 (or layers 402) and conductive layers 420, 421, 432, 436, 442, and 446 can be formed during package substrate processing (e.g., at panel level).

In one example, the package substrate 400 may be coupled or attached to multiple devices (e.g., die, chip, CPU, silicon die or chip, RF transceiver, etc.) and may be also coupled or attached to a printed circuit board (e.g., PCB 310). In one example, a piezoelectric SAW sensing device 430 (e.g., touch sensor) is formed with input transmit transducer 431, output receive transducer 440, and a touch region 480. The transducer 431 includes a first electrode 432, a second electrode 436, and a piezoelectric material 434 that generates surface acoustic wave 410 upon application of electrical signals 433 to the first and second electrodes. The wave 410 is received by the output receive transducer 440 which includes a first electrode 442, a second electrode 446, and a piezoelectric material 444. The transducer 440 generates output electrical signals 441.

In one example, voltage (electrical signal 433) is applied between the first and second electrodes 432 and 436, excites a surface wave 410 that propagates through the substrate 400 and is received by the receive transducer 440 on the other side. FIG. 4B illustrates a top view of the package substrate 400 having a package-integrated piezoelectric SAW sensing device (e.g., touch sensor), according to one embodiment. FIGS. 4A and 4B illustrate two interdigitated electrodes formed in a same conductive layer for each transducer, but alternatively, one electrode for each transducer may be positioned below or above the piezoelectric material. The spacing (e.g., approximately 150-400 microns) between the electrodes, electrode width (e.g., approximately 30-100 microns) and electrode thicknesses (e.g., approximately 0.1-2 microns) need to be optimized to maximize the power transduction to the surface mode wave. The surface mode wave propagates relatively close to the surface of the sensing device and is picked up by the receive transducer 440. The received amplitude of the wave will change if a user touches a surface of an input region 480 (e.g., input area, touch region) with their finger or using a stylus or if the input is located in close proximity to the input region. This change is detected by the receive transducer and is counted as an input event (e.g., touch input event). Similarly, the present design can be used for wave propagation on a case or enclosure of a device (e.g., wearable, computing device, mobile device, etc.) if this case or enclosure can be mechanically coupled to the package or board (e.g., using fasteners, adhesives or solder). In this example, the sensing device can determine whether a user is holding a case or enclosure that is protecting a device. In another example, the sensing device can determine how a user is holding a case or enclosure that is protecting a device (e.g., multiple input points, how many fingers are holding the device, location of input points on the device, etc.).

It will be appreciated that, in a system on a chip embodiment, the die may include a processor, memory, communications circuitry and the like. Though a single die is illustrated, there may be none, one or several dies included in the same region of the microelectronic device.

In one embodiment, the microelectronic device may be a crystalline substrate formed using a bulk silicon or a silicon-on-insulator substructure. In other implementations, the microelectronic device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of the present invention.

The microelectronic device may be one of a plurality of microelectronic devices formed on a larger substrate, such as, for example, a wafer. In an embodiment, the microelectronic device may be a wafer level chip scale package (WLCSP). In certain embodiments, the microelectronic device may be singulated from the wafer subsequent to packaging operations, such as, for example, the formation of one or more piezoelectric vibrating devices.

One or more contacts may be formed on a surface of the microelectronic device. The contacts may include one or more conductive layers. By way of example, the contacts may include barrier layers, organic surface protection (OSP) layers, metallic layers, or any combination thereof. The contacts may provide electrical connections to active device circuitry (not shown) within the die. Embodiments of the invention include one or more solder bumps or solder joints that are each electrically coupled to a contact. The solder bumps or solder joints may be electrically coupled to the contacts by one or more redistribution layers and conductive vias.

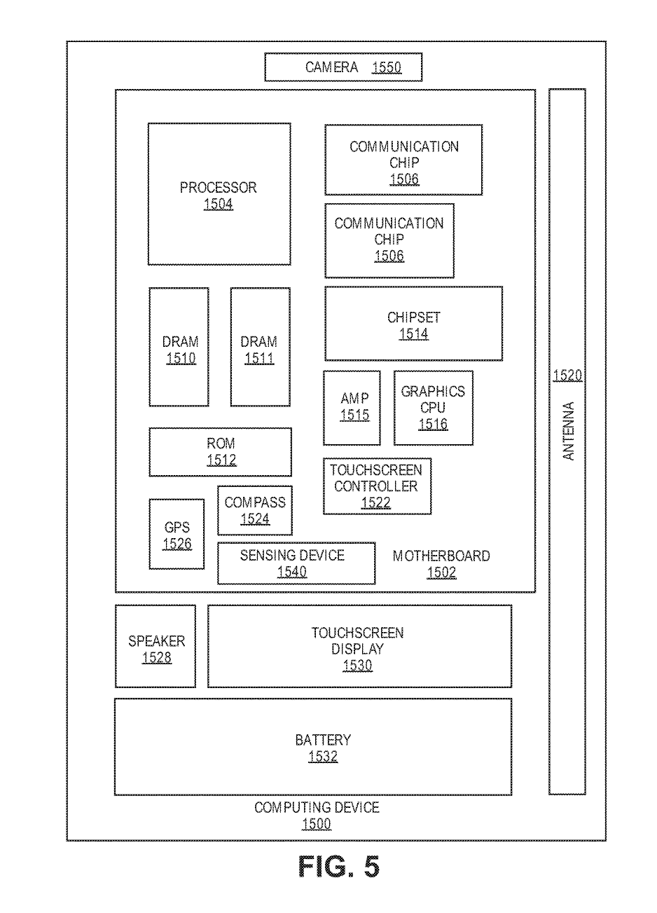

FIG. 5 illustrates a computing device 1500 in accordance with one embodiment of the invention. The computing device 1500 houses a board 1502. The board 1502 may include a number of components, including but not limited to a processor 1504 and at least one communication chip 1506. The processor 1504 is physically and electrically coupled to the board 1502. In some implementations the at least one communication chip 1506 is also physically and electrically coupled to the board 1502. In further implementations, the communication chip 1506 is part of the processor 1504.

Depending on its applications, computing device 1500 may include other components that may or may not be physically and electrically coupled to the board 1502. These other components include, but are not limited to, volatile memory (e.g., DRAM 1510, 1511), non-volatile memory (e.g., ROM 1512), flash memory, a graphics processor 1516, a digital signal processor, a crypto processor, a chipset 1514, an antenna 1520, a display, a touchscreen display 1530, a touchscreen controller 1522, a battery 1532, an audio codec, a video codec, a power amplifier 1515, a global positioning system (GPS) device 1526, a compass 1524, a transducer sensing device 1540 (e.g., a SAW sensing device, a touch sensor), a gyroscope, a speaker, a camera 1550, and a mass storage device (such as hard disk drive, compact disk (CD), digital versatile disk (DVD), and so forth).

The communication chip 1506 enables wireless communications for the transfer of data to and from the computing device 1500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1500 may include a plurality of communication chips 1506. For instance, a first communication chip 1506 may be dedicated to shorter range wireless communications such as Wi-Fi, WiGig and Bluetooth and a second communication chip 1506 may be dedicated to longer range wireless communications such as GPS, EDGE, GPRS, CDMA, WiMAX, LTE, Ev-DO, 5G, and others.

The processor 1504 of the computing device 1500 includes an integrated circuit die packaged within the processor 1504. In some implementations of the invention, the integrated circuit processor package or motherboard 1502 includes one or more devices, such as transducer sensing devices in accordance with implementations of embodiments of the invention. The term “processor” may refer to any device or portion of a device that processes electronic data from registers and/or memory to transform that electronic data into other electronic data that may be stored in registers and/or memory. The communication chip 1506 also includes an integrated circuit die packaged within the communication chip 1506. The following examples pertain to further embodiments.

Example 1 is a sensing device comprising a piezoelectric transmit transducer that receives input electrical signals and generates, in response to the input electrical signals, a surface acoustic wave to be transmitted along a surface of the sensing device which is integrated with an organic substrate. A piezoelectric receive transducer receives the surface acoustic wave and generates output electrical signals in response to the surface acoustic wave and an input region is integrated with the organic substrate. The input region is capable of receiving input which changes an acoustic amplitude of the surface acoustic wave.

In example 2, the subject matter of example 1 can optionally include the organic substrate being fabricated using panel level processing.

In example 3, the subject matter of any of examples 1-2 can optionally include the output electrical signals that are generated by the piezoelectric receive transducer being changed in response to the change in the acoustic amplitude of the surface acoustic wave.

In example 4, the subject matter of any of examples 1-3 can optionally include the piezoelectric receive transducer comprising first and second electrodes in contact with a piezoelectric material. The piezoelectric material generates the output electrical signals that correlate with an acoustic amplitude of the received acoustic wave.

In example 5, the subject matter of any of examples 1-4 can optionally include the piezoelectric transmit transducer comprising first and second electrodes in contact with a piezoelectric material. The first and second electrodes to receive the input electrical signals causing the piezoelectric transmit transducer to generate the surface acoustic wave.

In example 6, the subject matter of any of examples 1-5 can optionally include the first electrode and second electrode of the piezoelectric transmit transducer being interdigitated electrodes formed in a same conductive layer.

In example 7, the subject matter of any of examples 1-6 can optionally include the input region comprising a touch screen to receive a touch input.

Example 8 is a package substrate comprising a plurality of organic dielectric layers and a plurality of conductive layers to form the package substrate and a piezoelectric sensing device integrated within the package substrate. The piezoelectric sensing device includes a piezoelectric transmit transducer that receives input electrical signals and generates, in response to the input electrical signals, a surface acoustic wave to be transmitted along a surface of the sensing device. A piezoelectric receive transducer receives the surface acoustic wave and generates output electrical signals in response to the surface acoustic wave. An input region is capable of receiving input which changes an acoustic amplitude of the surface acoustic wave.

In example 9, the subject matter of example 8 can optionally include the package substrate being fabricated using panel level processing.

In example 10, the subject matter of any of examples 8-9 can optionally include output electrical signals that are generated by the piezoelectric receive transducer being changed in response to the change in the acoustic amplitude of the surface acoustic wave.

In example 11, the subject matter of any of examples 8-10 can optionally include the piezoelectric receive transducer comprising first and second electrodes in contact with a piezoelectric material. The piezoelectric material generates the output electrical signals that correlate with an acoustic amplitude of the received acoustic wave.

In example 12, the subject matter of any of examples 8-11 can optionally include the piezoelectric transmit transducer comprising first and second electrodes in contact with a piezoelectric material. The first and second electrodes receive the input electrical signals and this causes the piezoelectric transmit transducer to generate the surface acoustic wave.

In example 13, the subject matter of any of examples 8-12 can optionally include the first electrode and second electrode of the piezoelectric transmit transducer being interdigitated electrodes formed in a same conductive layer.

In example 14, the subject matter of any of examples 8-13 can optionally include the input region comprising a touch screen to receive a touch input.

Example 15 is a computing device comprising at least one processor to process data and a package substrate coupled to the at least one processor. The package substrate includes a plurality of organic dielectric layers and a plurality of conductive layers to form the package substrate which includes a piezoelectric sensing device having a piezoelectric transmit transducer to receive input electrical signals and to generate, in response to the input electrical signals, a surface acoustic wave to be transmitted along a surface of the sensing device. A piezoelectric receive transducer receives the surface acoustic wave and generates output electrical signals in response to the surface acoustic wave. An input region is capable of receiving input which changes an acoustic amplitude of the surface acoustic wave.

In example 16, the subject matter of example 15 can optionally include the package substrate being fabricated using panel level processing.

In example 17, the subject matter of any of examples 15-16 can optionally include the output electrical signals that are generated by the piezoelectric receive transducer being changed in response to the change in the acoustic amplitude of the surface acoustic wave.

In example 18, the subject matter of any of examples 15-17 can optionally include the piezoelectric receive transducer comprising first and second electrodes in contact with a piezoelectric material. The piezoelectric material generates the output electrical signals that correlate with an acoustic amplitude of the received acoustic wave.

In example 19, the subject matter of any of examples 15-18 can optionally include the piezoelectric transmit transducer comprising first and second electrodes in contact with a piezoelectric material. The first and second electrodes to receive the input electrical signals causing the piezoelectric transmit transducer to generate the surface acoustic wave.

In example 20, the subject matter of any of examples 15-19 can optionally include the input region comprising a touch screen to receive a touch input.

In example 21, the subject matter of any of examples 15-20 can optionally include the at least one processor being configured to determine a location of the touch input in proximity to the input region based on the output electrical signals.

In example 22, the subject matter of any of examples 15-21 can optionally include a decoder to receive the output signals and to generate the input signals.

1. A sensing device, comprising:
a piezoelectric transmit transducer to receive input electrical signals and to generate, in response to the input electrical signals, a surface acoustic wave to be transmitted along a surface of the sensing device which is integrated with an organic substrate;
a piezoelectric receive transducer to receive the surface acoustic wave and to generate output electrical signals in response to the surface acoustic wave; and
an input region integrated with the organic substrate, the input region capable of receiving input which changes an acoustic amplitude of the surface acoustic wave.

2. The sensing device of claim 1, wherein the organic substrate is fabricated using panel level processing.

3. The sensing device of claim 1, wherein the output electrical signals generated by the piezoelectric receive transducer change in response to the change in the acoustic amplitude of the surface acoustic wave.

4. The sensing device of claim 1, wherein the piezoelectric receive transducer comprises first and second electrodes in contact with a piezoelectric material, the piezoelectric material to generate the output electrical signals that correlate with an acoustic amplitude of the received acoustic wave.

5. The sensing device of claim 1, wherein the piezoelectric transmit transducer comprises first and second electrodes in contact with a piezoelectric material, the first and second electrodes to receive the input electrical signals causing the piezoelectric transmit transducer to generate the surface acoustic wave.

6. The sensing device of claim 5, wherein the first electrode and second electrode of the piezoelectric transmit transducer are interdigitated electrodes formed in a same conductive layer.

7. The sensing device of claim 1, wherein the input region comprises a touch screen to receive a touch input.

8. A package substrate comprising:
a plurality of organic dielectric layers and a plurality of conductive layers to form the package substrate; and
a piezoelectric sensing device integrated within the package substrate, the piezoelectric sensing device including a piezoelectric transmit transducer to receive input electrical signals and to generate, in response to the input electrical signals, a surface acoustic wave to be transmitted along a surface of the sensing device, a piezoelectric receive transducer to receive the surface acoustic wave and to generate output electrical signals in response to the surface acoustic wave, and an input region that is capable of receiving input which changes an acoustic amplitude of the surface acoustic wave.

9. The package substrate of claim 8, wherein the package substrate is fabricated using panel level processing.

10. The package substrate of claim 8, wherein the output electrical signals generated by the piezoelectric receive transducer change in response to the change in the acoustic amplitude of the surface acoustic wave.

11. The package substrate of claim 10, wherein the piezoelectric receive transducer comprises first and second electrodes in contact with a piezoelectric material, the piezoelectric material to generate the output electrical signals that correlate with an acoustic amplitude of the received acoustic wave.

12. The package substrate of claim 8, wherein the piezoelectric transmit transducer comprises first and second electrodes in contact with a piezoelectric material, the first and second electrodes to receive the input electrical signals causing the piezoelectric transmit transducer to generate the surface acoustic wave.

13. The package substrate of claim 12, wherein the first electrode and second electrode of the piezoelectric transmit transducer are interdigitated electrodes formed in a same conductive layer.

14. The package substrate of claim 8, wherein the input region comprises a touch screen to receive a touch input.

15. A computing device comprising:
at least one processor to process data; and
a package substrate coupled to the at least one processor, the package substrate including a plurality of organic dielectric layers and a plurality of conductive layers to form the package substrate which includes a piezoelectric sensing device having a piezoelectric transmit transducer to receive input electrical signals and to generate, in response to the input electrical signals, a surface acoustic wave to be transmitted along a surface of the sensing device, a piezoelectric receive transducer to receive the surface acoustic wave and to generate output electrical signals in response to the surface acoustic wave, and an input region that is capable of receiving input which changes an acoustic amplitude of the surface acoustic wave.

16. The computing device of claim 15, wherein the package substrate is fabricated using panel level processing.

17. The computing device of claim 15, wherein the output electrical signals generated by the piezoelectric receive transducer change in response to the change in the acoustic amplitude of the surface acoustic wave.

18. The computing device of claim 17, wherein the piezoelectric receive transducer comprises first and second electrodes in contact with a piezoelectric material, the piezoelectric material to generate the output electrical signals that correlate with an acoustic amplitude of the received acoustic wave.

19. The computing device of claim 15, wherein the piezoelectric transmit transducer comprises first and second electrodes in contact with a piezoelectric material, the first and second electrodes to receive the input electrical signals causing the piezoelectric transmit transducer to generate the surface acoustic wave.

20. The computing device of claim 15, wherein the input region comprises a touch screen to receive a touch input.

21. The computing device of claim 20, wherein the at least one processor is configured to determine a location of the touch input in proximity to the input region based on the output electrical signals.

22. The computing device of claim 20, further comprising:
a decoder to receive the output signals and to generate the input signals.
